(19) United States
(12) Patent Application Publication
(10) Pub. No.: US 2026/0140140 A1
(43) Pub. Date: May 21, 2026

(54) APPARATUS AND A METHOD FOR TESTING AN ELECTRONIC DEVICE

(71) Applicant: JCET STATS ChipPAC Korea Limited, Incheon (KR)

(72) Inventors: WonJung KIM, Incheon (KR); SeungJun BAEK, Incheon (KR); ZunBae MOON, Gyeonggi-do (KR)

(21) Appl. No.: 19/394,890

(22) Filed: Nov. 20, 2025

(30) Foreign Application Priority Data
Nov. 21, 2024 (CN) 202411675218.7

(51) Int. Cl. G01R 1/04; G01R 1/067; G01R 31/28; G01R 35/00

(52) U.S. Cl. CPC G01R 1/0466; G01R 1/06722; G01R 31/2863; G01R 35/005

(57) ABSTRACT

An apparatus and a method for testing an electronic device are provided. The apparatus comprises: a test board having a device placement region, a test region, and at least one signaling route; a test socket operably mounted on the test board, wherein the test socket comprises a socket body, and contact pins vertically extending through the socket body and movable vertically relative to the socket body; a calibration socket lid for mounting the test socket on the test board to press the plurality of contact pins against the test board but expose at least one target contact pin, such that a measurement result is generated by measuring an electrical characteristic associated with one of the at least one signaling route; and a device socket lid for mounting the test socket on the test board to press the contact pins against the test board.

### TECHNICAL FIELD

The present application relates generally to semiconductor technology, and more particularly, to an apparatus and a method for testing an electronic device.

### BACKGROUND OF THE INVENTION

The semiconductor industry is constantly faced with complex integration challenges as consumers want their electronics to be smaller, faster and higher performance with more and more functionalities packed into a single device. Electronic devices that have undergone complicated processing are subjected to various types of electrical tests so as to test their characteristics and for defects thereof.

To this end, a test socket is used to electrically connect metallic wires or contact pads of a test board (for example, a printed circuit board) mounted in test equipment with connectors or terminals of an electronic device to be tested. That is, when an electronic device is being tested, the test socket serves as an interface to electrically connect the test board of the test equipment with the electronic device under test. Establishing the connection between the test equipment and the electronic device under test may induce a path loss, which should be calibrated from test results of the electronic device to improve accuracy of the test results. However, it is difficult to measure the path loss induced by the test socket and the test board accurately by using existing test apparatuses.

Therefore, a need exists for an apparatus and a method for testing an electronic device.

### SUMMARY OF THE INVENTION

An objective of the present application is to provide an apparatus and a method for testing an electronic device to measure a path loss induced into a test result of the electronic device.

According to an aspect of the present application, an apparatus for testing an electronic device is provided. The apparatus comprises: a test board having a device placement region, a test region, and at least one signaling route each extending between a device contact pad in the device placement region and a test pad in the test region; a test socket operably mounted on the test board, wherein the test socket comprises a socket body, and a plurality of contact pins vertically extending through the socket body and movable vertically relative to the socket body; a calibration socket lid for accommodating the test socket, and mounting the test socket on the device placement region of the test board to press the plurality of contact pins against the test board but expose at least one target contact pin of the plurality of contact pins which is aligned with the at least one device contact pad respectively, such that a measurement result is generated by measuring an electrical characteristic associated with one of the at least one signaling route when the plurality of contact pins are pressed against the test board by the calibration socket lid; and a device socket lid for accommodating the test socket and the electronic device, and mounting the test socket on the device placement region of the test board to press the plurality of contact pins against the test board via the electronic device, such that the electronic device is testable via the at least one signaling route of the test board.

In another aspect of the present application, a method for testing an electronic device using a test board and a test socket is provided, wherein the test board has a device placement region, a test region, and at least one signaling route each extending between a device contact pad in the device placement region and a test pad in the test region; the test socket comprises a socket body, and a plurality of contact pins vertically extending through the socket body and movable vertically relative to the socket body, and wherein the method comprises: mounting the test socket onto the device placement region of the test board by a calibration socket lid to press the plurality of contact pins against the test board but expose at least one target contact pin of the plurality of contact pins which are aligned with the at least one device contact pad respectively; generating a measurement result by measuring an electrical characteristic associated with one of the at least one signaling route when the plurality of contact pins are pressed against the test board by the calibration socket lid; removing the calibration socket lid from the test socket and the test board; mounting the electronic device onto the test socket to align a plurality of conductive pads formed on the electronic device with the plurality of contact pins, respectively; mounting the test socket and the electronic device onto the device placement region of the test board by a device socket lid to press the plurality of contact pins against the test board via the electronic device, so as to set up an electrical connection between the electronic device and the test board through the contact pins; and testing the electronic device and calibrating a test result of the electronic device according to the measurement result.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1D illustrate an apparatus for testing an electronic device according to a first embodiment of the present application.

FIGS. 2A to 2C illustrate various steps of a method for testing an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, when an electronic device is being tested by a test apparatus including fixtures such as a test socket and a test board, a path loss may be inevitably induced into test results generated by the test apparatus. To be more specific, the test socket may include pogo pins which help establish electrical connections between the electronic device and the test board to test the electronic device. During this testing process, the path loss of the pogo pins may inevitably occur and be incorporated within a test result of the electronic device. Therefore, it is desired to calibrate or remove the path loss from the test result, so as to improve accuracy of the test result of the electronic device. However, it is difficult to accurately and conveniently measure path losses using conventional test apparatuses.

Some solutions have been provided to measure path losses of pogo pins. For example, a simulation of the path loss, or a pre-measured result of the path loss provided by pogo pin vendors may be used for calibration of a test result of an electronic device under test, instead of an actual measurement of the path loss when the electronic device is being tested. However, since this calibration information which is generated or measured beforehand is obtained in environments different from an actual testing environment of the electronic device, the accuracy of the calibration information of the path loss may still be unsatisfactory.

To address this issue, an apparatus and a method for testing an electronic device are provided. The apparatus includes a test board, a test socket including contact pins, and a calibration socket lid for mounting the test socket on a test board. When the test socket is mounted onto the test board by the calibration socket lid, the contact pins are pressed against the test board by the calibration socket lid, and at least one target contact pin of the contact pins is exposed from the calibration socket lid. As such, a measurement result, such as a measurement of a path loss is generated when the contact pins are pressed against the test board by the calibration socket lid. The measurement result may then be used for calibrating a test result of the electronic device using the same test socket and test board. During a subsequent testing process of the electronic device, the contact pins are pressed against the test board to set up an electrical connection between the electronic device and the test board. Since the measurement result is generated when the contact pins are pressed against the test board, an environment for calibration can be generated which mimics the actual testing environment where the electronic device is being tested. Thus, the measurement result may have a satisfactory accuracy, thereby resulting in a more reliable test result of the electronic device.

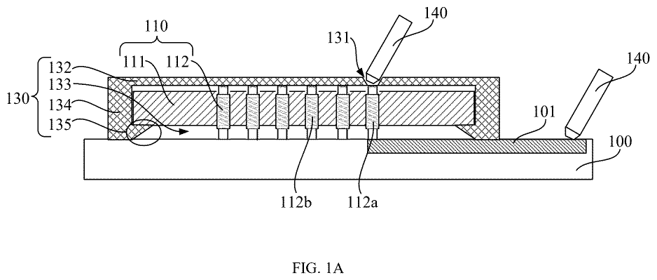

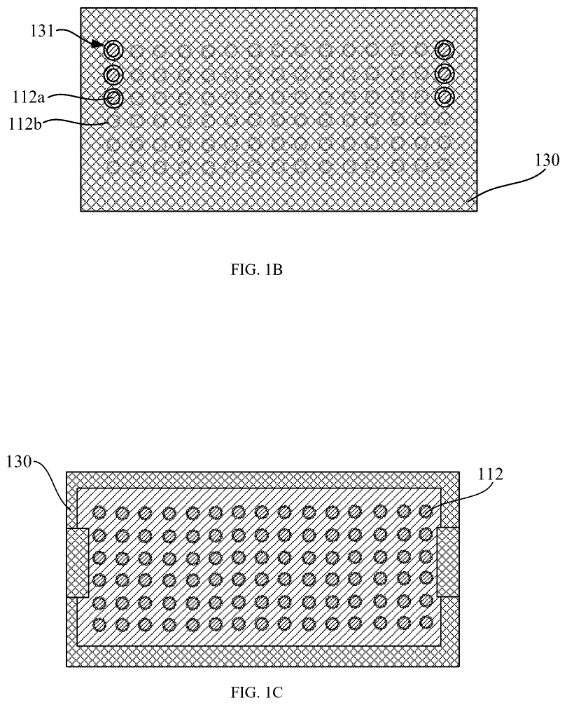

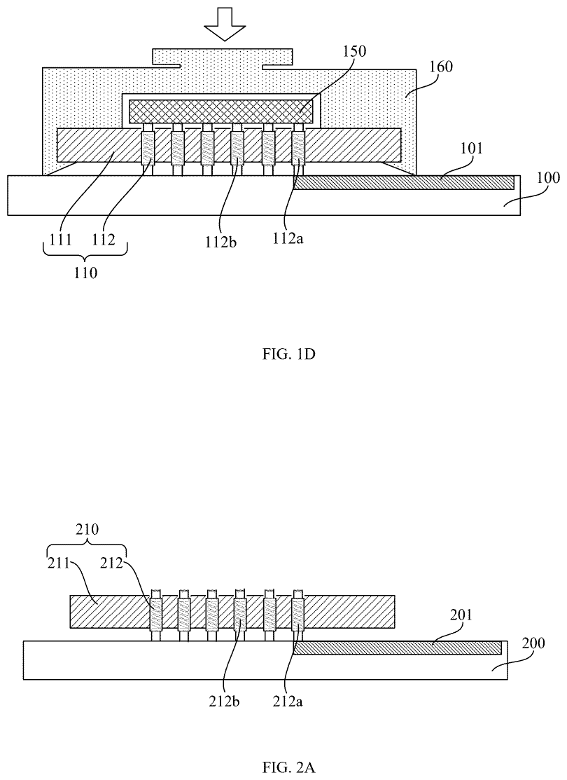

FIGS. 1A to 1D illustrate an apparatus for testing an electronic device according to a first embodiment of the present application. The apparatus can operate in a test mode under which a test result of the electronic device can be generated, and in another calibration mode under which calibration information for the test result can be generated. Here, FIGS. 1A to 1C illustrate the calibration mode and certain parts of the apparatus for generating a measurement result for calibrating a test result of an electronic device. In particular, FIG. 1A illustrates a sectional view of a test board, a test socket and a calibration socket lid of the apparatus. FIG. 1B illustrates a top view of the test socket and the calibration socket lid shown in FIG. 1A, and FIG. 1C illustrates a bottom view of the test socket and the calibration socket lid shown in FIG. 1A. FIG. 1D illustrates a sectional view of the apparatus when it operates in the test mode for testing the electronic device, including the test board and the test socket shown in FIGS. 1A to 1C, and a device socket lid.

As shown in FIG. 1A, the apparatus includes a test board 100 which serves as a base of the apparatus. The test board 100 can be electrically connected with an electronic device when it is being tested. Also, the test board 100 is electrically coupled to testing equipment such as a multimeter with or without a signal generator for testing the electronic device. In some embodiments, the test board 100 includes a device placement region for placing a testing fixture (e.g., a test socket 110) and the electronic device under test. Furthermore, the test board 100 includes a test region where a test tool (e.g., a test probe) can be placed and/or connected such that the test tool can be electrically coupled with the electronic device to collect a measurement of the electronic device before or during a testing process of the electronic device. In some embodiments, the device placement region may be a central zone of the test board 100, and the test region may be a peripheral zone of the test board 100. Alternatively, the test region may be at a back side of the test board 100 as long as it is convenient for the test tool to get access to. Furthermore, the test board 100 includes at least a device contact pad in the device placement region and at least a test pad in the test region of the test board 100. A signaling route 101 such as a metallic wire extends between a pair of the device contact pad and the test pad, which is used for transmitting signals between the electronic device and the external test equipment. For example, during the testing of the electronic device, the signaling route 101 may be coupled with the signal generator of testing equipment to receive and apply to the electronic device a test signal. In some embodiments, the signaling route 101 may have a respective layout corresponding to a layout of the electronic device, for example, a specific length corresponding to a size of the electronic device. Also, the device contact pad may be formed at a specific position of the test board 100, which indicates the specific position of the signaling route 101 corresponding to the layout of the electronic device.

Still referring to FIG. 1A, the apparatus includes a test socket 110 operably mounted on the test board 100. During the testing process, the test socket 110 is used for accommodating the electronic device therewithin, and at the same time, providing an electrical connection between the electronic device and the test board 100, so as to build a complete test environment or system to test the electronic device. To be more specific, the test socket 110 includes a socket body 111 which may be constructed to have a cuboid structure. The socket body 111 may have a plurality of through holes extending from its front surface to its back surface. Moreover, the test socket 110 includes a plurality of contact pins 112 vertically extending through the socket body 111 and accommodated within the plurality of through holes, respectively. The contact pins 112 are movable vertically relative to the socket body 111. During the testing process of the electronic device, the contact pins 112 establish an elastic and electrical connection between the electronic device and the test board 100. Top portions and bottom portions of the contact pins 112 may be exposed from the front surface and the bottom surface of the socket body 111 respectively to allow for a convenient connection with the electronic device and the test board 100.

Referring to FIG. 1A in conjunction with FIGS. 1B and 1C, the contact pins 112 include at least one target contact pin 112a, each of which is aligned with a device contact pad and is electrically coupled with a signaling route 101 during the testing of the electronic device. Apart from the at least one target contact pin 112a, the contact pins 112 also include at least one non-target contact pin 112b which may not be electrically coupled with the signaling route 101. The at least one non-target contact pin 112b may be used for other purposes such as powering, grounding or connection with other signal routes (e.g., non-target signaling routes). The test board 100 may include at least one additional device contact pad in the device placement region which is used for coupling the at least one non-target contact pin 112b. The non-target contact pin 112b and the target contact pin 112a may have the same structure. In some embodiments, the contact pins 112 include pogo pins. Each pogo pin 112 includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with the top contactor at its top end, and can be in contact with the bottom contactor at its bottom end. As such, the pogo pins 112 can be movable vertically relative to the socket body 111 with the coil spring providing an elastic connection between the electronic device and the test board 100. With these configurations, when the electronic device is being tested by the test socket 110, the top contactors of the pogo pins 112 can be in contact with conductive pads of the electronic device, and the bottom contactors can be in contact with the device contact pad and the addition device contact pad in the device placement region. Additionally, the top contactors and the bottom contactors are exposed from the front surface and the back surface of the socket body 111. When the electronic device is being tested by the test socket 110, the contact pins 112 may be pressed against the test board 100 to set up a reliable electrical connection between the electronic device and the test board 100, which builds a complete test environment or system to test the electronic device. In some other embodiments, the contact pins may include other types of elastic connectors, such as elastic conductive pillars.

As shown in FIG. 1A, the apparatus further includes a calibration socket lid 130 which mounts the test socket 110 onto the device placement region of the test board 100. To be more specific, the calibration socket lid 130 includes a casing having a backside opening 133 at its backside and a cover portion 132 at its front side. The cover portion 132 may be a flat plate which covers the at least one non-target contact pin 112b, and has at least one hole 131 for exposing the at least one target contact pin 112a such that a test tool (e.g., a test probe 140) can be in contact with the at least one target contact pin 112a through the hole 131. In some embodiments, the at least one hole 131 may have a larger size at its top portion and may shrink to a smaller size at its bottom portion, which forms a truncated shape. For example, a top portion of the hole(s) 131 may have a size larger than the target contact pin(s) 112a, while a bottom portion of the hole(s) 131 may have a size smaller than at least a portion of the target contact pin(s) 112a. In this way, it is easier for the probe 140 to get access to the target contact pin 112a through the hole 131 while the target contact pin(s) 112a can still be pressed by the calibration socket lid 130. The casing also has two vertical portions 134 which are parallelly arranged on two opposite sides of the cover portion 132 and extending downward from the cover portion 132. The cover portion 132 and the vertical portions 134 together define the backside opening 133 of the casing through which the test socket 110 can be inserted into the casing. Furthermore, the calibration socket lid 130 includes a pair of tabs 135 formed at the backside opening 133, or particularly extending from the vertical portions 134 towards each other. The pair of tabs 135 may serve as fasteners to secure the test socket 110 within the casing after its insertion into the casing. In some embodiments, the pair of tabs 135 may have a triangle shaped cross section, where one side of the triangle tab 135 is in contact with the test socket 110. In some other embodiments, the pair of tabs 135 may have a truncated triangle shaped cross section, with its topside which can be in contact with the test socket 110 having a smaller length, thereby the calibration socket lid 130 may be easier to be removed from the test socket 110 in a later process.

After assembled with the test socket 110, the calibration socket lid 130 may be placed onto the device placement region of the test board 100 with the vertical portions 134 of the casing being in contact with the test board 100. The height of the casing may be slightly smaller than the height of the contact pins 112. As such, when the calibration socket lid 130 with the test socket 110 is disposed onto the test board 100, the at least one non-target contact pin 112b and the at least one target contact pin 112a can be pressed against the test board 100 by the cover portion 132 of the calibration socket lid 130. The at least one target contact pin 112a and the at least one non-target contact pin 112b are aligned with the device contact pad(s) and the additional device contact pad(s) respectively to allow for an electrical connection between the test socket 110 and the test board 100. In some other embodiments, an alignment mark may be formed on a specific position of the device placement region of the test board 100 to facilitate accurate positioning of the test socket 110 onto the test board 100, thereby ensuring the alignment of the contact pins 112 with the respective device contact pads. The mark may be a recess on the test board 100 which is used for receiving the bottom portion of the calibration socket lid 130. It can be appreciated that the calibration socket lid 130 can be placed on the device placement region in any other suitable alignment manners.

In this embodiment, a test tool, such as a pair of test probes 140 can be in contact with the at least one target contact pin 112a, and the test pad in the test region of the test board 100 (as shown in FIG. 1A) respectively. In this way, a measurement result is generated by measuring an electrical characteristic associated with the at least one signaling route 101 through the probes 140. The electrical characteristic may be a radio frequency (RF) characteristic, such as a path loss within the test apparatus including the contact pins 112 and the test board 100. To be more specific, as shown in FIG. 1A, a pair of probes 140 can be used to measure a path loss of an electrical path between a top portion of the target contact pin 112a and the respective test pad in the test region. The path loss of the electrical path may include the path losses of the target contact pin 112a and the signaling route 101. When the electrical characteristic is being measured, the at least one non-target contact pin 112b is pressed against the test board 100 by the calibration socket lid 130, and the at least one target contact pin 112a is also pressed against the test board 100 by the calibration socket lid 130 during the measurement. This provides an improved accuracy of the measurement result since the calibration socket lid 130 creates a measuring environment that exactly mimics the actual testing environment where the electronic device is being tested. Additionally, since the test socket 110 has a rectangle shaped cross section without a sidewall, it is more convenient for the probes 140 to approach the test socket 110 without any obstacle, thereby improving contact reliability between the probe 140 and the target contact pin 112a as well as probe durability.

In some embodiments, more than one target contact pins 112a are included within the contact pins 112, as illustrated in FIG. 1B. In this case, each of the target contact pin 112a is coupled with a signaling route within the test board 100. A measurement of the electrical characteristic may be carried out between one of target contact pins 112a and one of the signaling routes 101, respectively. The measurement may be carried out individually for each pair of the target contact pin 112a and the signaling route 101, to generate multiple measurement results for the target contact pins 112a and the signaling routes 101. The measurement results can be used for calibrating a test result of the electronic device which may be obtained in a later step, as will be described below.

In some other embodiments, the calibration socket lid 130 may be a flat plate without the vertical portions 134, and the flat plate has at least one hole 131 for exposing the at least one target contact pin 112a. The flat plate may be disposed above the contact pins 112 but not in direct contact with them before the measurement of the electrical characteristic. When the electrical characteristic is being measured, the flat plate is moved downwards to press the at least one non-target contact pin 112b against the test board 100. In this way, the structure of the calibration socket lid 130 as well as an assembly process of the calibration socket lid 130 and the test socket 110 can be simplified. Also, the contact pins 112 may not be pressed before the actual measurement of the electrical characteristic, which protects the contact pins 112 from being overworn and prolongs a lifetime of the test socket 110. Also, it is easier to remove the calibration socket lid 130 before the testing step of the electronic device. In some embodiments, the calibration socket lid 130 may be mechanically coupled to a driver or actuator which automatically controls the calibration socket lid 130 to move upward or downward. In some other embodiments, the calibration socket lid 130 may be controlled manually by at least one handwheel or other similar drive mechanism.

In some other embodiments, the calibration socket lid 130 may include a lid frame with an inner opening exposing all of the contact pins 112, and a plurality of flake inserts movably inserted within the lid frame to cover the at least one non-target contact pin 112b. Each of the plurality of flake inserts may have a designed pattern. At least one flake insert with a designed pattern can be chosen from the plurality of flake inserts to cover the at least one non-target contact pin 112b. To be more specific, for testing of various electronic devices, the layout of target contact pin(s) 112a and the non-target contact pin(s) 112b may be different. A specific set of flake inserts with designed patterns may be chosen from the plurality of the flake inserts according to the layout of the non-target contact pin(s) 112b. Then the chosen set of flake inserts may be assembled together and inserted within the lid frame to achieve a required layout that covers the at least one non-target contact pin 112b but exposes the at least one target contact pin 112a. In this way, the calibration socket lid 130 with the lid frame and the plurality of flake inserts can be used for testing different electronic devices with various layouts, which provides improved testing flexibility and saves cost.

In some other embodiments, the socket body 111 may include a sidewall at its periphery that protrudes upward from a front surface of the socket body 111, which forms a housing with a cavity at its center. In this case, the calibration socket lid 130 may include a slot aligned with the sidewall that allows the sidewall to pass therethrough. The test socket 110 and the calibration socket lid 130 may be assembled together with the following steps. Firstly, the calibration socket lid 130 can be disposed onto the test socket 110 by penetrating the sidewall of the test socket 110 through the slot of the calibration socket lid 130. At the same time, the pair of tabs 135 may be pulled away from each other to allow for the accommodation of the socket body 111 within the casing of the calibration socket lid 130. Afterwards, the pair of tabs 135 may return to the original position to clamp and secure the test socket 110 within the casing. Alternatively, the calibration socket lid 130 can be a flat plate having the slot passing therethrough.

After the electrical characteristic has been measured, the calibration socket lid 130 can be removed from the test socket 110. An electronic device to be tested can be mounted on the test socket 110. Additionally, a device socket lid is introduced to assemble the electronic device and the test socket 110, so as to test the electronic device using the apparatus.

FIG. 1D illustrates a sectional view of the apparatus operating under the test mode to perform the testing step of an electronic device 150. The apparatus now includes the test board 100 and the test socket 110 shown in FIGS. 1A to 1C, and a device socket lid 160.

As shown in FIG. 1D, after the calibration socket lid 130 is removed from the test socket 110, the electronic device 150 is mounted onto the test socket 110. The electronic device 150 may include various types of electronic modules, such as a Radio Frequency (RF) device, a semiconductor chip, a resistor, a capacitor, a System in Package (SiP) module or other large-sized devices with complex functionalities. The electronic module included within the electronic device 150 may be encapsulated by a mold cap. Moreover, the electronic device 150 has a plurality of conductive pads at its bottom surface to provide an electrical connection between the electronic device 150 and the test socket 110. To be more specific, each of the conductive pads can be aligned with one of the contact pins 112.

The device socket lid 160 can be used for pressing the electronic device 150 against the test board 100. To be more specific, the device socket lid 160 has a lid cavity where the electronic device 150 and the test socket 110 can be accommodated. The device socket lid 160 is constructed to have a shape that mates with the configuration of the electronic device 150 and the test socket 110. During a testing process of the electronic device 150, an external force can be applied onto the device socket lid 160 and then be transferred to the electronic device 150, thereby the electronic device 150 may press the contact pins 112, including the target contact pin(s) 112a and the non-target contact pin(s) 112b against the test board 100 to set up an elastic electrical connection between the electronic device 150 and the test board 100.

In this way, a test result is generated by testing the electronic device 150 through the at least one signaling route 101 of the test board 100. Then the test result is calibrated according to the measurement result associated with the at least one signaling route 101, which is generated using the calibration socket lid 130 (as shown in FIGS. 1A to 1C) before the testing process, thereby improving the accuracy of the test result.

As mentioned before, in some embodiments, the measurement result which is measured using the calibration socket lid 130 before the testing process may be a path loss of the apparatus including the contact pins 112. As shown in FIG. 1D, during the testing step of the electronic device 150, the contact pins 112 are pressed against the test board 100 by the external force applied from the device socket lid 160. Referring back to FIGS. 1A to 1C, the path loss of the apparatus is measured when the at least one non-target contact pin 112b and the at least one target contact pin 112a are pressed against the test board 100 by the calibration socket lid 130, which is the same environment as the testing environment used for testing the electronic device 150 in FIG. 1D. In other words, when the path loss of the apparatus is measured, the contact pins 112 are pressed by the calibration socket lid 130, which exactly mimics the working status of the contact pins 112 during the actual testing step of the electronic device 150. Thus, the path loss measured with the assistance of the calibration socket lid 130 may have a greatly improved accuracy. When the path loss is used to calibrate the test result of the electronic device 150, a more accurate test result of the electronic device 150 can be obtained. Additionally, when the path loss is measured, the contact pins 112 are coupled with the test board 100 which is also used during the actual testing step of the electronic device 150. Thus, the path loss is measured by taking into account the effect of the mismatching of heterojunction between the contact pins 112 and the signaling route 101 of the test board 100 during the actual testing step of the electronic device 150, which also contributes to the accurate calibration of the test result.

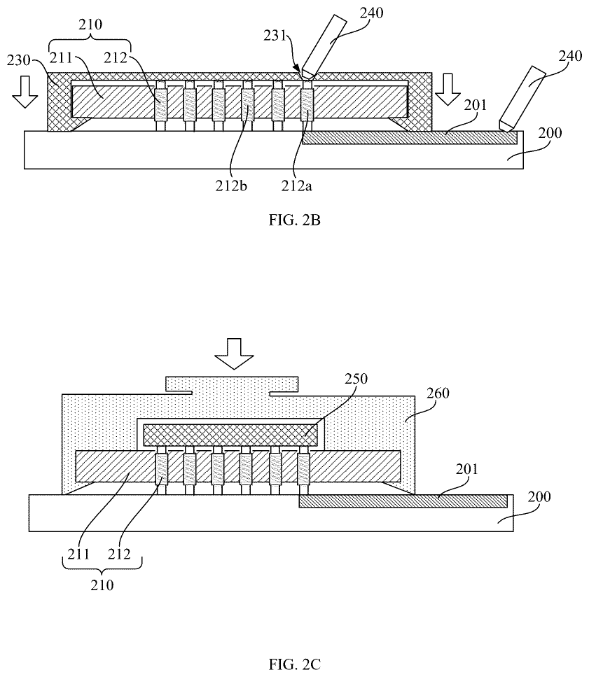

FIGS. 2A to 2C illustrate various steps of a method for testing an electronic device according to a second embodiment of the present application. In some embodiments, the method can be implemented by the apparatus shown in FIGS. 1A to 1D.

As shown in FIG. 2A, a test board 200 and a test socket 210 are provided. The test board 200 has a device placement region, a test region, and at least one signaling route 201 each extending between a device contact pad in the device placement region and a test pad in the test region. The test socket 210 includes a socket body 211, and a plurality of contact pins 212 vertically extending through the socket body 211 and movable vertically relative to the socket body 211. The contact pins 212 include at least one non-target contact pin 212b and at least one target contact pin 212a. In some embodiments, the contact pins 212 may be pogo pins. The test socket 210 is disposed onto the test board 200. The at least one device contact pad is aligned with the at least one target contact pin 212a, respectively. Additionally, the test board 200 may include at least one additional device contact pad in the device placement region which is aligned with the at least one non-target contact pin 212b. The details of the test board 200 and the test socket 210 may be similar to those illustrated with respect to the test board 100 and the test socket 110 shown in FIGS. 1A to 1C, which will not be elaborated in detail here for simplicity.

Next, as shown in 2B, a calibration socket lid 230 is provided, which includes a casing having at its back side a backside opening and at its front side a cover portion. The cover portion has at least one hole 231. The calibration socket lid 230 also includes a pair of tabs formed at the backside opening and extending towards each other. The test socket 210 is inserted into the backside opening of the calibration socket lid 230, such that the at least a portion of the at least one target contact pin 212a is exposed from the at least one hole 231 of the cover portion and the at least one non-target contact pin 212b is covered by the cover portion.

Furthermore, the test socket 210 can be secured within the casing by the pair of tabs. After the insertion of the test socket 210 into the backside opening of the calibration socket lid 230, the non-target contact pin 212b and the target contact pin 212a may be pressed against the test board 200 by the calibration socket lid 230, so as to establish an electrical connection between the test socket 210 and the test board 200. To be more specific, the calibration socket lid 230 may be placed onto the device placement region of the test board 200. The height of the casing, i.e., the total height of the backside opening and the tabs may be slightly smaller than the height of the contact pins 212. As such, when the calibration socket lid 230 with the test socket 210 is disposed onto the test board 200, the at least one non-target contact pin 212b and the target contact pin 212a can be pressed against the test board 200 by the cover portion 232 of the calibration socket lid 230. For example, in some embodiments, the at least one hole 231 may have a larger size at its top portion and may shrink to a smaller size at its bottom portion, which forms a truncated shape. For example, a top portion of the hole(s) 231 may have a size larger than the target contact pin(s) 212a, while a bottom portion of the hole(s) 231 may have a size smaller than at least a portion of the target contact pin(s) 212a. In this way, the target contact pin(s) 212a can still be pressed by the calibration socket lid 230. In some other embodiments, the test socket 210 may first be mounted onto the test board 200 and then be inserted into the calibration socket lid 230.

Next, a test tool, such as a pair of probes 240 are provided. One of the probes 240 is in contact with the at least one target contact pin 212a, and the other probe 240 is in contact with the test pad in the test region of the test board 200. In this way, a measurement result is generated by measuring an electrical characteristic associated with the at least one signaling route 201 through the probes 240 when the at least one non-target contact pin 212b and the target contact pin(s) 212a are pressed against the test board 200. The electrical characteristic may be a RF characteristic, such as a path loss within the test apparatus including the contact pins 212 and the test board 200. To be more specific, as shown in FIG. 2B, a pair of probes 240 can be used to measure a path loss of an electrical path between a top portion of the target contact pin 212a and the respective test pad in the test region. The path loss of the electrical path may include the path losses of the target contact pin 212a and the signaling route 201.

As shown in FIG. 2C, the calibration socket lid 230 is removed from the test socket 210, and an electronic device 250 is mounted onto the test socket 210. The electronic device 250 has a set of conductive pads at its bottom surface to provide an electrical connection between the electronic device 250 and the test socket 210. To be more specific, each of the conductive pads are aligned with one of the contact pins 212, respectively.

Next, a device socket lid 260 is disposed above the electronic device 250 and the test socket 210 to press the electronic device 250 against the test board 200. Thus, the contact pins 212, including the at least one non-target contact pin 212b and the at least one target contact pin 212a are pressed against the test board 200 via the electronic device 250, thereby setting up an electrical connection between the electronic device 250 and the test board 200 through the contact pins 212.

Next, a test result is generated by testing the electronic device 250 through the at least one signaling route 201 of the test board 200. Then the test result is calibrated according to the measurement result, which is generated using the calibration socket lid 230 (as shown in FIG. 2B) before the testing step, thereby improving the accuracy of the test result. For example, the measurement result (e.g., path loss) can be removed from the test result to calibrate the test result.

While the exemplary apparatus and method for testing an electronic device of the present application is described in conjunction with corresponding figures, it will be understood by those skilled in the art that modifications and adaptations to the apparatus and method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for testing an electronic device, wherein the apparatus comprises:
a test board having a device placement region, a test region, and at least one signaling route each extending between a device contact pad in the device placement region and a test pad in the test region;
a test socket operably mounted on the test board, wherein the test socket comprises a socket body, and a plurality of contact pins vertically extending through the socket body and movable vertically relative to the socket body;
a calibration socket lid for accommodating the test socket, and mounting the test socket on the device placement region of the test board to press the plurality of contact pins against the test board but expose at least one target contact pin of the plurality of contact pins which is aligned with the at least one device contact pad respectively, such that a measurement result is generated by measuring an electrical characteristic associated with one of the at least one signaling route when the plurality of contact pins are pressed against the test board by the calibration socket lid; and
a device socket lid for accommodating the test socket and the electronic device, and mounting the test socket on the device placement region of the test board to press the plurality of contact pins against the test board via the electronic device, such that the electronic device is testable via the at least one signaling route of the test board.

2. The apparatus of claim 1, further comprising:
a test module for testing the electronic device through the test board when the test socket and the electronic device are mounted on the test board via the device socket lid, wherein the test module is further configured to calibrate a test result of the electronic device according to the measurement result associated with the at least one signaling route.

3. The apparatus of claim 1, wherein generating a measurement result by measuring an electrical characteristic associated with one of the at least one signaling route when the plurality of contact pins are pressed against the test board by the calibration socket lid further comprises:
generating a measurement result by measuring an electrical characteristic associated with an electrical path between one of the at least one target contact pin and respective one of the at least one test pad when the plurality of contact pins are pressed against the test board by the calibration socket lid.

4. The apparatus of claim 1, wherein the contact pins comprise pogo pins.

5. The apparatus of claim 1, wherein the calibration socket lid comprises a flat front surface.

6. The apparatus of claim 5, wherein the calibration socket lid comprises:
a casing for receiving the test socket, wherein the casing has at its back side a backside opening through which the test socket can be inserted into, and at its front side a cover portion for pressing the plurality of contact pins towards the backside opening, and wherein the cover portion has at least one hole for exposing the at least one target contact pin; and
a pair of tabs formed at the backside opening and extending towards each other, wherein the pair of tabs are configured to secure the test socket within the casing after its insertion into the casing.

7. The apparatus of claim 5, wherein the calibration socket lid is a flat plate having at least one hole for exposing the at least one target contact pin.

8. The apparatus of claim 1, wherein the socket body comprises a sidewall at its periphery that protrudes upward from a front surface of the socket body; and the calibration socket lid comprises a slot aligned with the sidewall that allows the sidewall to pass therethrough when the test socket is mounted on the test board via the calibration socket lid.

9. A method for testing an electronic device using a test board and a test socket, wherein the test board has a device placement region, a test region, and at least one signaling route each extending between a device contact pad in the device placement region and a test pad in the test region; the test socket comprises a socket body, and a plurality of contact pins vertically extending through the socket body and movable vertically relative to the socket body, and wherein the method comprises:
mounting the test socket onto the device placement region of the test board by a calibration socket lid to press the plurality of contact pins against the test board but expose at least one target contact pin of the plurality of contact pins which are aligned with the at least one device contact pad respectively;
generating a measurement result by measuring an electrical characteristic associated with one of the at least one signaling route when the plurality of contact pins are pressed against the test board by the calibration socket lid;
removing the calibration socket lid from the test socket and the test board;
mounting the electronic device onto the test socket to align a plurality of conductive pads formed on the electronic device with the plurality of contact pins, respectively;
mounting the test socket and the electronic device onto the device placement region of the test board by a device socket lid to press the plurality of contact pins against the test board via the electronic device, so as to set up an electrical connection between the electronic device and the test board through the contact pins; and
testing the electronic device and calibrating a test result of the electronic device according to the measurement result.

10. The method of claim 9, wherein the contact pins comprise pogo pins.

11. The method of claim 9, wherein the calibration socket lid comprises a flat front surface.

12. The method of claim 11, wherein the calibration socket lid comprises a casing having at its back side a backside opening and at its front side a cover portion, wherein the cover portion has at least one hole; and a pair of tabs formed at the backside opening and extending towards each other; and
wherein mounting the test socket onto the device placement region of the test board by a calibration socket lid comprises:
inserting the test socket into the backside opening of the calibration socket lid such that the pair of tabs secure the test socket within the casing, wherein the at least one hole of the cover portion exposes the at least one target contact pin; and
attaching the calibration socket lid and the test socket onto the device placement region of the test board such that the plurality of contact pins are pressed towards the test board by the cover portion.

13. The method of claim 9, wherein generating a measurement result by measuring an electrical characteristic associated with one of the at least one signaling route when the plurality of contact pins are pressed against the test board by the calibration socket lid further comprises: generating a measurement result by measuring an electrical characteristic associated with an electrical path between one of the at least one target contact pin and respective one of the at least one test pad when the plurality of contact pins are pressed against the test board by the calibration socket lid.
